(19) United States
(12) Patent Application Publication
(10) Pub. No.: US 2021/0005501 A1
(43) Pub. Date: Jan. 7, 2021

(54) SUBSTRATE PROCESSING APPARATUS

(71) Applicant: WONIK IPS CO., LTD., Pyeongtaek-si Gyeonggi-do (KR)

(72) Inventors: Dong Bum KANG, Hwaseong-si Gyeonggi-do (KR); NANYI ZHAO, Ansan-si Gyeonggi-do (KR)

(73) Assignee: WONIK IPS CO., LTD., Pyeongtaek-si Gyeonggi-do (KR)

(21) Appl. No.: 16/871,567

(22) Filed: May 11, 2020

(30) Foreign Application Priority Data
Jul. 1, 2019 (KR) 10-2019-0078968
Jul. 1, 2019 (KR) 10-2019-0078969
Feb. 3, 2020 (KR) 10-2020-0012678
Feb. 3, 2020 (KR) 10-2020-0012679

(51) Int. Cl. H01L 21/687; H01L 21/67; C23C 16/458; C23C 16/455; C23C 16/46; C23C 16/44; C23F 1/08

(52) U.S. Cl. CPC H01L 21/68735; H01L 21/67069; H01L 21/68742; H01L 21/68771; C23F 1/08; C23C 16/45565; C23C 16/46; C23C 16/4412; C23C 16/4584

(57) ABSTRACT

A substrate support includes a disk having a disk shape to support at least one substrate, at least one pocket groove which is formed to be concave from an upper surface of the disk in a shape corresponding to the substrate such that at least an edge portion of the substrate is seated therein, a free space forming portion which is spaced inwardly at a predetermined distance from an edge of the pocket groove and formed to be concave from at least a part of a bottom surface of the pocket groove so as to define a stepped portion that supports at least the edge portion of the substrate and forms a free space below the substrate when the substrate is seated on the stepped portion, and an exhaust passage which connects an outer circumferential surface of the disk to at least a part of the free space forming portion.

### CROSS-REFERENCE TO RELATED APPLICATION (S)

This application claims the benefit of Korean Patent Application No. 10-2019-0078968, filed on Jul. 1, 2019, Korean Patent Application No. 10-2019-0078969, filed on Jul. 1, 2019, Korean Patent Application No. 10-2020-0012678, filed on Feb. 3, 2020, and Korean Patent Application No. 10-2020-0012679, filed on Feb. 3, 2020, in the Korean Intellectual Property Office, the entire disclosures of which are incorporated herein by reference for all purposes.

### BACKGROUND

### 1. Field

The present invention relates to a substrate processing apparatus, and more particularly, to a substrate processing apparatus which has a substrate support for receiving a substrate and is capable of processing the substrate.

### 2. Description of Related Art

Generally, in order to manufacture a semiconductor device, a display device, or a solar cell, various processes are performed in a substrate processing apparatus including a process chamber in a vacuum environment. For example, processes, such as loading a substrate in a process chamber and depositing a thin film on the substrate or etching the thin film, may be performed. At this time, the substrate is supported on a substrate support installed in the process chamber, and a process gas may be injected into the substrate through a shower head which is installed above the substrate support, facing the substrate support.

Meanwhile, in order to improve productivity, a substrate processing apparatus capable of processing a plurality of substrates at a time by supplying the plurality of substrates all at once to a process chamber has been proposed. Such a substrate processing apparatus is provided with a plurality of pocket grooves so that the plurality of substrates can be arranged radially at equal angles around a rotation axis of the substrate support on an upper surface of the substrate support. In this case, the substrates that are seated in the pocket grooves are generally placed in the pocket grooves by their own weight.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

However, such a conventional substrate processing apparatus has a problem in that the substrate is dislodged from a pocket groove due to various process conditions, such as an instantaneous gas flow change or a sudden pressure change in a process chamber, during the process of processing the substrate. Particularly, when it is inevitable to increase the rotation and lifting speed of a substrate support in order to improve the throughput, the possibility of the substrate being dislodged from the pocket groove may be further increased. As such, there is a problem in that a process defect of the substrate occurs due to a problem in which the substrate is dislodged from the pocket groove during the process of processing the substrate.

Objectives of the present invention are to solve various problems including the aforementioned problems and to provide a substrate processing apparatus capable of preventing a substrate from being dislodged from a pocket groove of a substrate support during the process of processing a plurality of substrates. However, the objectives of the present invention are merely exemplary, and the scope of the present invention is not limited by these objectives.

In one general aspect, there is provided a substrate processing apparatus including: a process chamber in which a processing space for processing a substrate is formed; a substrate support provided in the processing space of the process chamber to support the substrate; and a shower head which is provided in an upper portion of the process chamber to face the substrate support and injects a processing gas toward the substrate support, wherein the substrate support includes a disk formed in a disk shape to support at least one substrate, at least one pocket groove which is formed to be concave from an upper surface of the disk in a shape corresponding to the substrate such that at least an edge portion of the substrate is seated therein, a free space forming portion which is spaced inwardly at a predetermined distance from an edge of the pocket groove and formed to be concave from at least a part of a bottom surface of the pocket groove so as to define a stepped portion that supports at least the edge portion of the substrate and forms a free space below the substrate when the substrate is seated on the stepped portion, and an exhaust passage which connects an outer circumferential surface of the disk to at least a part of the free space forming portion.

The free space forming portion may include a first heat transfer portion formed to protrude from a center portion of a bottom surface of the free space forming portion to the same height as that of the stepped portion so as to help heat transfer from the disk to the substrate when the substrate is seated on the stepped portion.

The free space forming portion may include a second heat transfer portion that extends from one side of the first heat transfer portion in a direction of the exhaust passage and is formed to protrude from the bottom surface of the free space forming portion to the same height as that of the stepped portion to help heat transfer from the disk to the substrate when the substrate S is seated on the stepped portion.

The free space forming portion may include a third heat transfer portion formed in the exhaust passage to protrude from a bottom surface of the free space forming portion to the same height as that of the stepped portion so as to help heat transfer from the disk to the substrate when the substrate is seated on the stepped portion.

The free space forming portion may include a plurality of lift pin receiving grooves which are formed to protrude from a bottom surface of the free space forming portion to the same height as that of the stepped portion and each include a through-hole formed to accommodate therein a substrate lift pin.

The substrate processing apparatus may further include a cover plate disposed in the pocket groove to allow at least a part of the substrate to be seated and including a plurality of communication holes communicating with the free space forming portion.

The cover plate may include a plate body formed in a circular plate shape and a first projection portion that is formed to protrude from a center portion of a lower surface of the plate body to a bottom surface of the free space forming portion and helps heat transfer from the disk to the substrate.

The cover plate may include a second projection portion that is formed to protrude from the lower surface of the plate body and has a through-hole to accommodate therein a substrate lift pin, and the free space forming portion may include a concave groove which is formed to be concave from the bottom surface thereof at a position corresponding to the second projection portion and accommodates the second projection portion.

The plate body may be disposed on the stepped portion to allow the entire substrate to be seated on an upper portion of the plate body.

The plate body may be disposed in the free space forming portion positioned inner than the stepped portion at the same height as that of the stepped portion such that the edge portion of the substrate is supported by the stepped portion and a center portion of the substrate is seated on the plate body.

The cover plate may include an extended portion that is formed to extend from one side of the plate body in a shape corresponding to a shape of the exhaust passage and covers an upper portion of the exhaust passage.

The exhaust passage may have an inlet portion that is formed on at least a portion in contact with an outer circumferential surface of the disk and is deeper than a bottom surface of the free space forming portion.

The free space forming portion may include a first heat transfer portion formed to protrude from a center portion of a bottom surface of the free space forming portion to the same height as that of the stepped portion so as to help heat transfer from the disk to the substrate when the substrate is seated on the stepped portion.

The free space forming portion may include a fourth heat transfer portion that is formed to protrude from the bottom surface of the free space forming portion to the same height as that of the stepped portion to help heat transfer from the disk to the substrate when the substrate is seated on the stepped portion and is spaced apart from the first heat transfer portion in a direction of the exhaust passage.

A plurality of fourth heat transfer portions may be disposed to be spaced apart from the first heat transfer portion in the direction of the exhaust passage.

Some of the fourth heat transfer portions may be extended to the outer circumferential surface of the disk to divide the exhaust passage into two sections and the inlet portion of the exhaust passage may be divided into two parts by the fourth heat transfer portion.

The free space forming portion may include a fifth heat transfer portion that is formed between the stepped portion and the first heat transfer portion at the same height as that of the stepped portion and protrudes in a shape of a ring which is open toward a direction of the exhaust passage.

The fifth heat transfer portion may include a plurality of lift pin receiving grooves formed to be concave from a surface of the fifth heat transfer portion in a shape corresponding to a substrate lift pin so as to accommodate therein a plurality of substrate lift pins.

The substrate processing apparatus may further include a cover portion which covers at least the inlet portion of the exhaust passage such that the inlet portion is in the form of a tunnel.

The exhaust passage may include an inclined portion with a depth linearly increasing from the free space forming portion to the inlet portion, between the free space forming portion and the inlet portion.

Other features and aspects will be apparent from the following detailed description, the drawings, and the claims.

### BRIEF DESCRIPTION OF THE DRAWINGS

FIG. 1 is a cross-sectional view schematically showing a substrate processing apparatus according to one embodiment of the present invention.

FIG. 2 is a perspective view schematically showing a substrate support of the substrate processing apparatus of FIG. 1.

FIG. 3 is a cross-sectional view schematically showing a cross section taken along line III-III of FIG. 2.

FIG. 4 is a cross-sectional view schematically showing a cross section taken along line IV-IV of FIG. 2.

FIG. 5 is a perspective view schematically showing a substrate support according to another embodiment of the present invention.

FIG. 6 is a perspective view schematically showing a substrate support according to still another embodiment of the present invention.

FIGS. 7 and 8 are front and rear perspective views schematically showing a cover plate of the substrate support of FIG. 6.

FIG. 9 is a cross-sectional view schematically showing a cross section taken along the line IX-IX of FIG. 6.

FIG. 10 is a cross-sectional view schematically showing a cross-section taken along the line X-X of FIG. 6.

FIG. 11 is a cross-sectional view schematically showing another embodiment of the cross section taken along the line IX-IX of FIG. 6.

FIG. 12 is a perspective view schematically showing a substrate support according to still another embodiment of the present invention.

FIG. 13 is a cross-sectional view schematically showing a cross section taken along line XIII-XIII in FIG. 12.

FIG. 14 is an image showing results of analyzing the pressure generated on upper and lower surfaces of a substrate seated in a pocket groove of a substrate support according to one embodiment of the present invention.

FIG. 15 is a perspective view schematically showing a substrate support according to another embodiment of the present invention.

FIG. 16 is a cross-sectional view schematically showing a cross section taken along line III-III of FIG. 15.

FIG. 17 is a cross-sectional view schematically showing a cross-section taken along line IV-IV of FIG. 15.

FIG. 18 is a cross-sectional view schematically showing another embodiment of a cross section taken along line IV-IV of FIG. 15.

FIG. 19 is a perspective view schematically showing a substrate support according to another embodiment of the present invention.

FIG. 20 is an image showing results of analyzing the pressure generated on upper and lower surfaces of a substrate seated in a pocket groove of a substrate support according to another embodiment of the present invention.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

Exemplary embodiments will now be described more fully with reference to the accompanying drawings. The invention may, however, be embodied in many different forms and should not be construed as being limited to the embodiments set forth herein; rather, these embodiments are provided so that this disclosure will be thorough and complete. In the drawings, the thicknesses or sizes of layers may be exaggerated for clarity and convenience of explanation.

Hereinafter, the present invention will be described in detail by explaining embodiments of the invention with reference to the attached drawings. Variations from the shapes of the illustrations may result, for example, from manufacturing techniques and/or acceptable tolerances. Thus, unless explicitly claimed, the invention should not be construed as being limited to the particular shapes of regions illustrated herein but may include deviations in shapes that result, for example, from manufacturing.

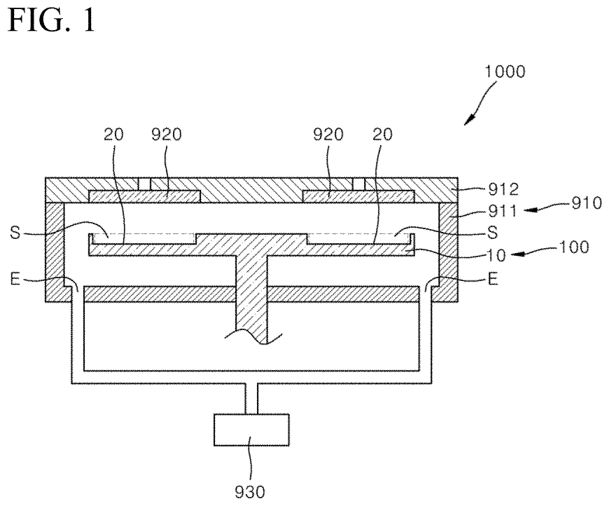

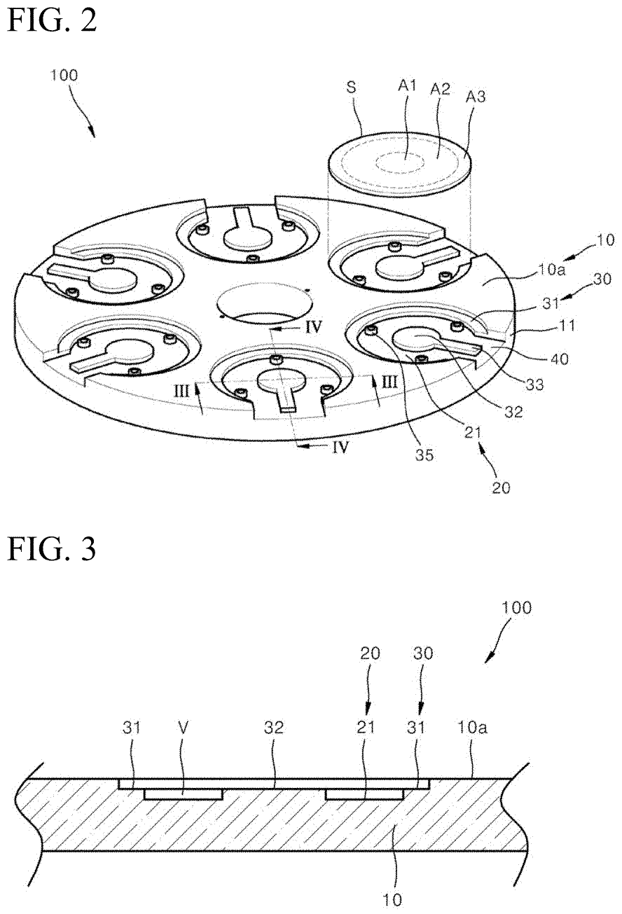

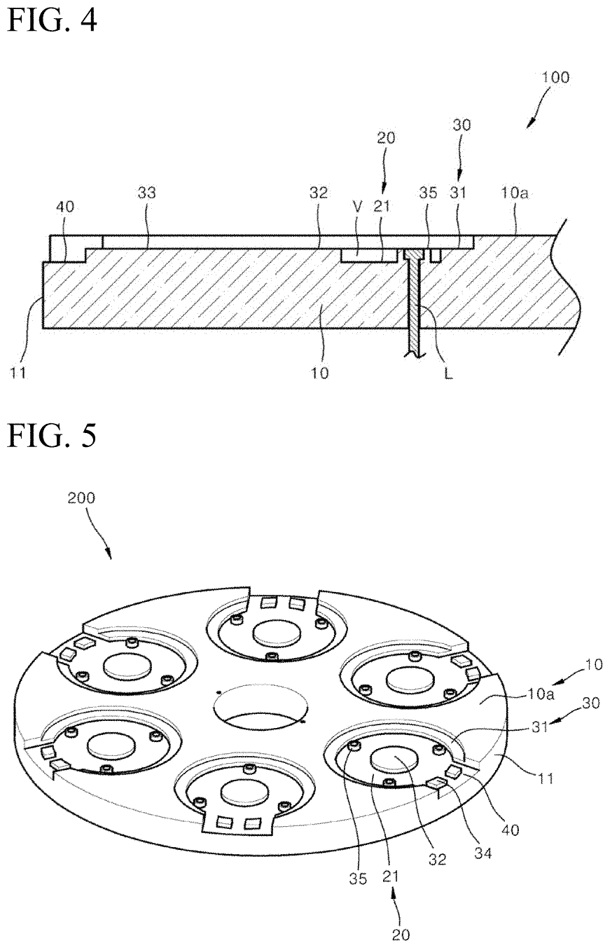

FIG. 1 is a cross-sectional view schematically showing a substrate processing apparatus 1000 according to one embodiment of the present invention, and FIG. 2 is a perspective view schematically showing a substrate support 100 of the substrate processing apparatus 1000 of FIG. 1. FIG. 3 is a cross-sectional view schematically showing a cross section taken along line III-III of FIG. 2, and FIG. 4 is a cross-sectional view schematically showing a cross section taken along line IV-IV of FIG. 2. FIG. 5 is a perspective view schematically showing a substrate support 200 according to another embodiment of the present invention.

First, as shown in FIG. 1, the substrate processing apparatus 1000 according to one embodiment of the present invention may largely include a process chamber 910, a substrate support 100, and a shower head 920.

As shown in FIG. 1, the process chamber 910 may include a chamber body 911 provided with a processing space in which a substrate S can be processed. More specifically, the chamber body 911 is provided inside with a processing space formed in a circular or square shape, and processes, such as depositing or etching a thin film on the substrate S supported on the substrate support 100 installed in the processing space, may be performed.

In addition, a plurality of exhaust ports E may be installed on a lower part of the chamber body 911 in a shape surrounding the substrate support 100. The exhaust ports E may be connected through piping to a vacuum pump 930 installed outside the process chamber 910 to suck in air inside the processing space of the process chamber 910, thereby exhausting various process gases from the processing space or create a vacuum environment inside the processing space.

In addition, although not shown, a gate, which is a passage through which the substrate S can be loaded or unloaded into the processing space, may be formed on a side surface of the chamber body 911. Further, the processing space of the chamber body 911 with an open upper part may be closed by a top lid 912.

As shown in FIG. 1, the substrate support 100 may be provided in a processing space of the process chamber 910 so as to support a plurality of substrates S and may be installed rotatably about a central axis of the process chamber 910. For example, the substrate support 100 may be a substrate support structure, such as a susceptor or a table which can support the substrate S. In this case, a shower head 920 may be provided in the upper portion of the process chamber 910, facing the substrate support 100, and may inject various processing gases, such as a process gas and a cleaning gas, toward the substrate support 100.

As shown in FIG. 2, a disk 10 of the substrate support 100 according to one embodiment of the present invention may be formed in a disk shape so as to support at least one substrate S and be rotatably installed in the processing space of the process chamber 910. For example, the disk 10 may be heated to a process temperature by a heater installed separately on the outside of the disk 10, so that the substrate S seated in the pocket groove 30 may be heated to the temperature at which a process of depositing a thin film or a process of etching the thin film is possible.

More specifically, the heater, spaced apart from the disk 10, may be separately installed below the disk 10. However, the installation position of the heater is not necessarily limited thereto, and may be installed at the bottom of the disk 10 to be in contact with the disk 10, or may be installed inside the disk 10. In addition, the disk 10 may be installed at various positions where the disk 10 can be easily heated to the process temperature.

Also, as shown in FIGS. 2 to 4, the substrate support 100 may be provided with at least one substrate support 100 which is formed to be concave from an upper surface 10a of the disk 10 in a shape corresponding to the substrate S such that an edge portion A3 of the substrate S can be seated. More specifically, a plurality of pocket grooves 30 may be arranged along a circumferential direction of the disk 10 around a rotation axis of the disk 10 such that the plurality of substrates S can be seated on the substrate support 100.

In addition, a free space forming portion 20 of the substrate support 100 may be spaced inwardly at a predetermined distance from an edge of the pocket groove 30 and formed to be concave from at least a part of a bottom surface of the pocket groove 30 so as to define a stepped portion 31 that supports at least the edge portion A3 of the substrate S. Accordingly, when the substrate S is seated on the stepped portion 31, a free space V may be formed below the substrate S.

For example, in the process of processing the substrate S, when a vacuum environment is formed by sucking in air from the inside of the process chamber 910 through an exhaust port E installed at the lower portion of the process chamber 910, vacuum pressure may be formed in the free space V of the pocket groove 30 formed by the free space forming portion 20, thereby generating a suction force that fixes the substrate S to the pocket groove 30.

In this case, an exhaust passage 40 connecting an outer circumferential surface 11 of the disk 10 to at least a portion of the free space forming portion 20 may be formed to allow at least a portion of the free space forming portion 20 to communicate with the outside of the disk 10, so that the air inside the free space V can be smoothly exhausted through the exhaust passage 40 and thereby a vacuum pressure can be formed.

Thus, when the substrate S is seated in the pocket groove 30 of the substrate support 100, the free space V may be formed below the substrate S by the free space forming portion 20. At this time, when the air inside the process chamber 910 is sucked through the exhaust port E formed on the lower portion of the process chamber 910, the air inside the free space V may be discharged to the exhaust port E through the exhaust passage 40, thereby generating vacuum pressure in the free space V. Accordingly, the vacuum pressure generates a force to pull the lower surface of the substrate S seated on the pocket groove 30, so that the substrate S is prevented from being dislodged from the pocket groove 30 during the process of processing the substrate S.

In the free space forming portion 20, a heat transfer structure may be formed in a wide variety of forms in order to effectively transfer heat of the disk 10 heated to the process temperature by the heater to the substrate S while forming the free space V below the substrate (S) seated in the pocket groove 30.

For example, as shown in FIGS. 2 to 4, the free space forming portion 20 according to one embodiment of the present invention may include a first heat transfer portion 32 and a plurality of lift pin receiving grooves 35 wherein the first heat transfer portion 32 is formed in a pillar shape protruding from the center of a bottom surface 21 of the free space forming portion 20 to the same height as that of the stepped portion 31 to support a center portion A1 of the substrate S and help heat transfer from the disk 10 to the substrate S when the substrate S is seated on the stepped portion 31 and the plurality of lift pin receiving grooves 35 are formed to protrude from the bottom surface 21 of the free space forming portion 20 to the same height as the stepped portion 31 to support at least a part of a middle portion A2 of the substrate S and each include a through-hole formed to accommodate therein a substrate lift pin L.

As such, the first heat transfer portion 32 and the lift pin receiving grooves 35 may serve to uniformly transfer heat generated from the disk 10, while supporting the lower surface of the substrate S in such a manner that the free space S can be formed below the substrate S in the pocket groove 30.

At this time, the heat of the disk 10 may not be effectively transferred to the substrate S in an open area of the free space S opened by the exhaust passage 40, which may cause a non-uniform temperature distribution across the substrate S. For this reason, the free space forming portion 20 may include a second heat transfer portion 33 that extends from one side of the first heat transfer portion 32 in a direction of the exhaust passage 40 and is formed in a pillar shape protruding from the bottom surface 21 of the free space forming portion 20 to the same height as that of the stepped portion 31 to help heat transfer from the disk 10 to the substrate S when the substrate S is seated on the stepped portion 31.

Therefore, in the substrate support 100 according to one embodiment of the present invention, the overall donut-shaped free space V is formed in the pocket groove 30 by the free space forming portion 20, and the vacuum pressure is generated in the free space V when the vacuum environment is formed inside the process chamber 910, and thus the substrate S is prevented from being dislodged from the pocket groove 30 due to various changes in process conditions, such as an instantaneous gas flow change or a sudden pressure change in the process chamber 910 during the process of processing the substrate S.

In this case, the first heat transfer portion 32 and the second heat transfer portion 33 may be provided in the center portion of the free space V to form a key shape as a whole and may uniformly transfer the heat of the disk 10 heated to the process temperature to the entire area of the substrate S, while supporting the substrate S in such a manner that the free space V can be formed inside the pocket groove 30.

In addition, as shown in FIG. 5, the free space forming portion 20 of the substrate support 200 according to another embodiment of the present invention may include, instead of the second heat transfer portion 33, third heat transfer portions 34 in the exhaust passage 40, at least one of which is formed in a pillar shape protruding from the bottom surface 21 of the free space forming portion 20 to the same height as that of the stepped portion 31 to help heat transfer from the disk 10 to the substrate S when the substrate S is seated on the stepped portion 31. For example, a plurality of third heat transfer portions 34 may be disposed in the exhaust passage 40, along the circumferential direction of the disk 10.

Accordingly, the free space forming portion 20 of the substrate support 200 according to another embodiment of the present invention may allow the area of the free space V to be formed wider, thereby increasing the vacuum pressure generated in the free space V and hence increasing further a suction force for the substrate S generated in the free space V inside the pocket groove 30.

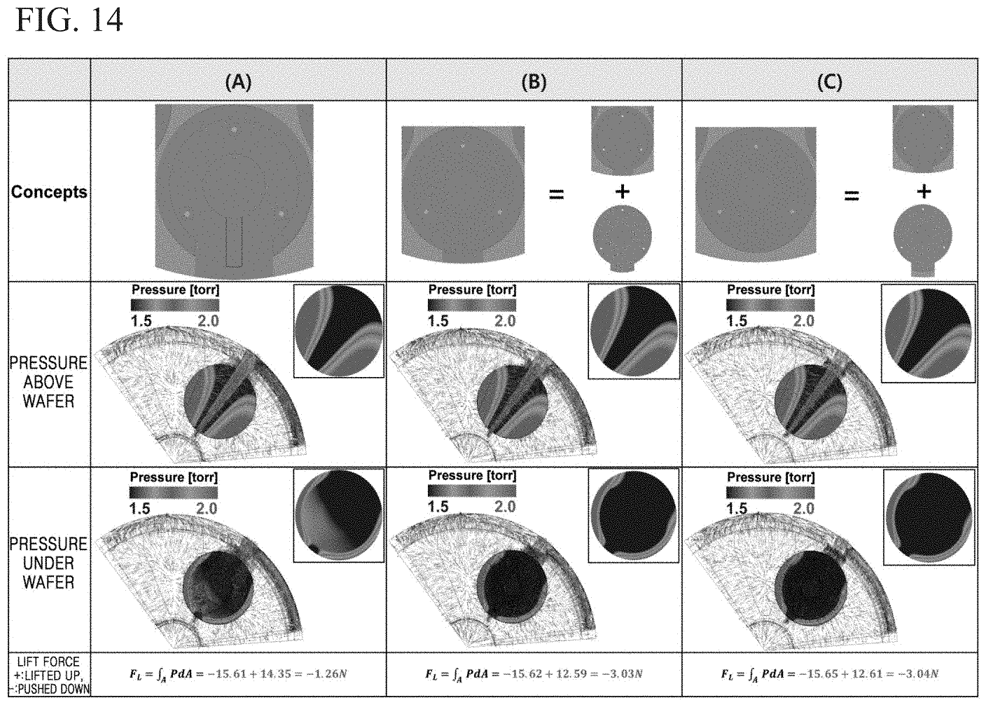

Therefore, as shown in (A) of FIG. 14, the substrate supports 100 and 200 according to various embodiments of the present invention and the substrate processing apparatus 1000 including the substrate support 100 or 200 may induce the pressure generated in the lower portion of the substrate S to be smaller than the pressure generated in the upper portion of the substrate S, thereby effectively preventing the substrates S from being dislodged from the pocket grooves 30 of the substrate supports 100 and 200 during the process of processing the plurality of substrates S. Accordingly, it is possible to prevent the process defect of the substrate S from occurring due to a problem in which the substrate S is dislodged from the pocket groove 30 during the process of processing the substrate S and also to increase the yield.

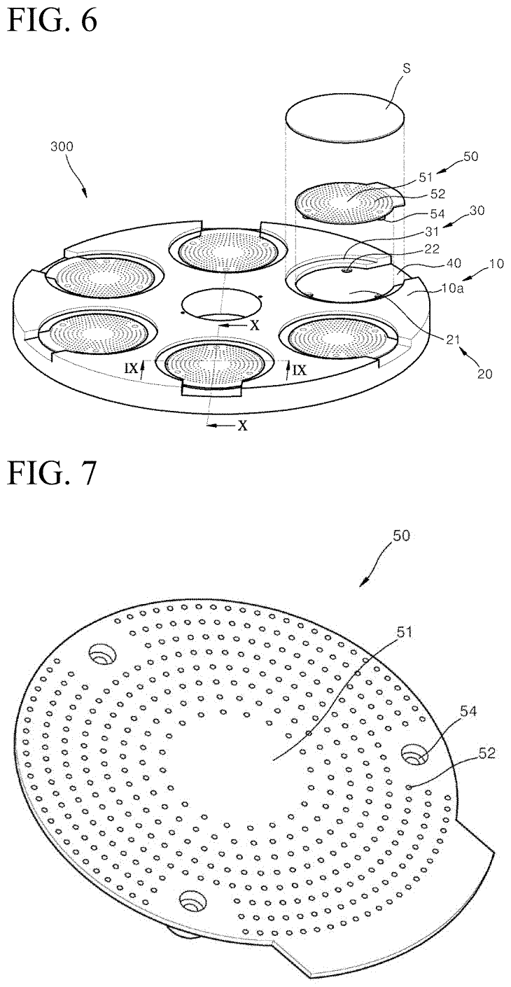

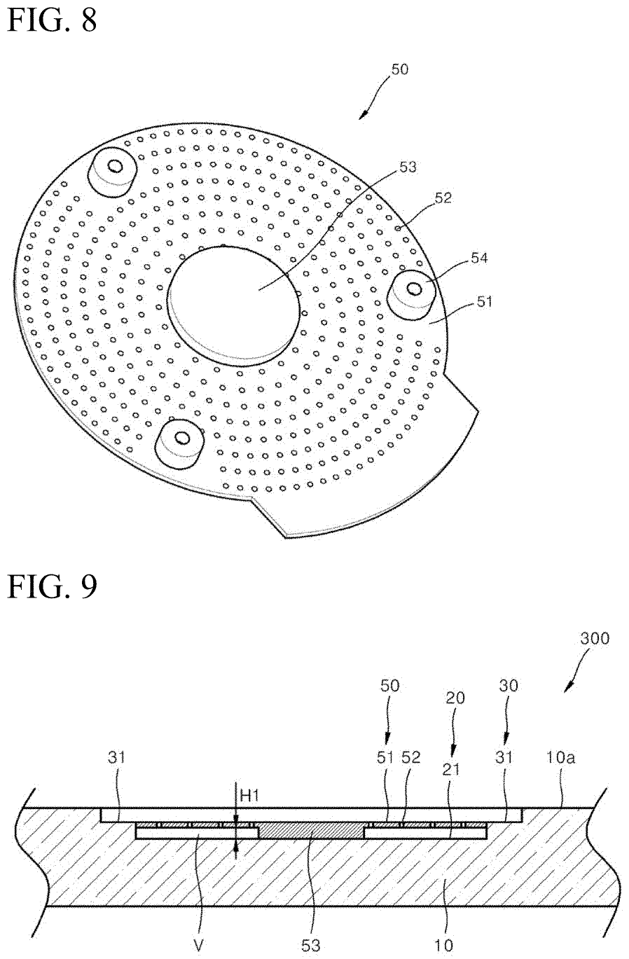

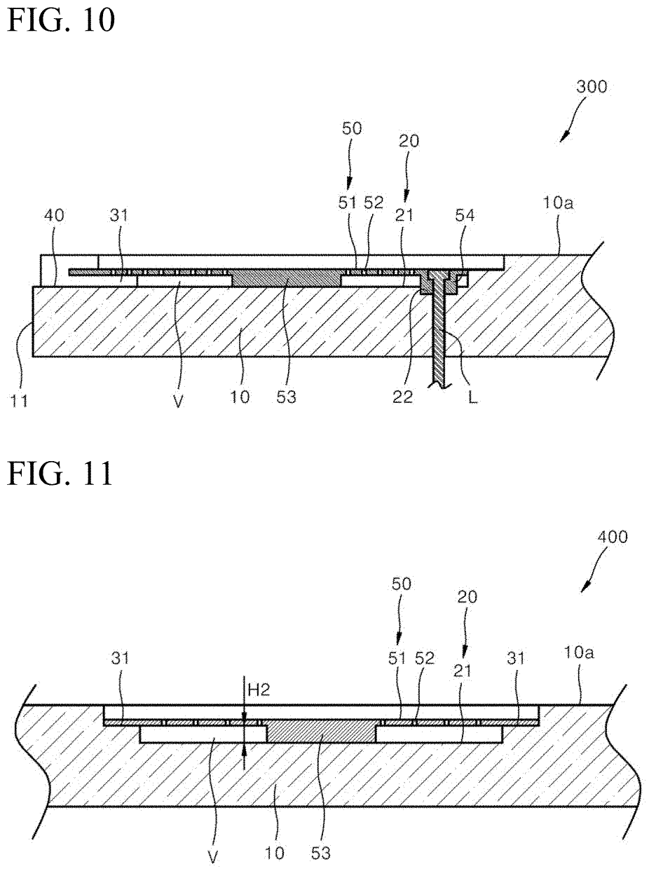

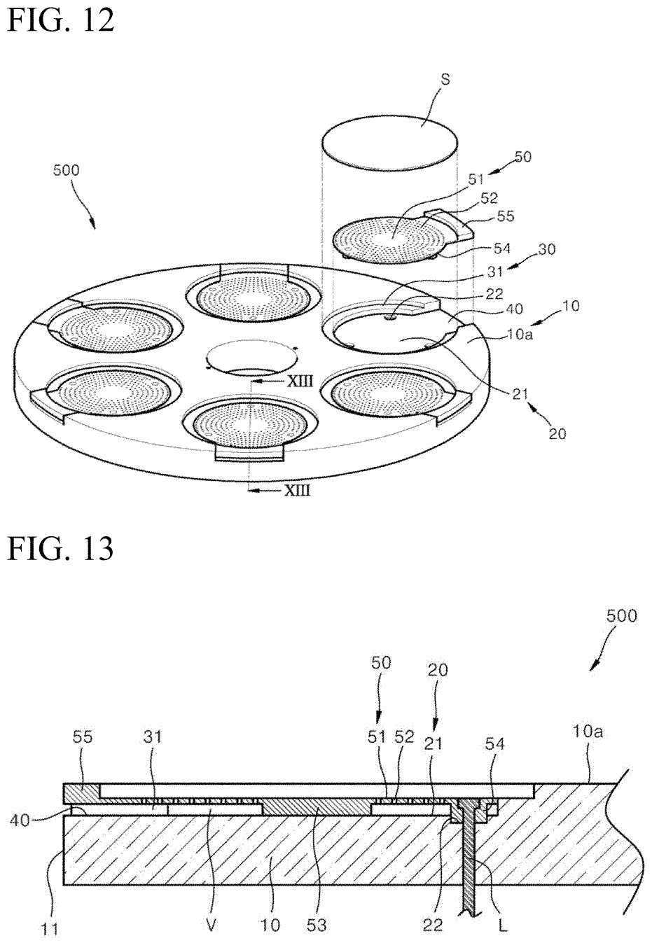

FIG. 6 is a perspective view schematically showing a substrate support 300 according to still another embodiment of the present invention, and FIGS. 7 and 8 are front and rear perspective views schematically showing a cover plate 50 of the substrate support 300 of FIG. 6. In addition, FIG. 9 is a cross-sectional view schematically showing a cross section taken along line IX-IX of FIG. 6, FIG. 10 is a cross-sectional view schematically showing a cross section taken along line X-X of FIG. 6, and FIG. 11 is a cross-sectional view schematically showing another embodiment of the cross section taken along the line IX-IX of FIG. 6. Further, FIG. 12 is a perspective view schematically showing a substrate support 500 according to yet another embodiment of the present invention and FIG. 13 is a cross-sectional view schematically showing a cross section taken along line XIII-XIII of FIG. 12.

As shown in FIG. 6, the substrate support 300 according to another embodiment of the present invention may include a cover plate 50 that is disposed in a pocket groove 30 so that at least a portion of the substrate S can be seated and includes a plurality of communication holes 52 communicating with a free space forming portion 20.

For example, as shown in FIGS. 6 to 10, the cover plate 50 may include a plate body 51 formed in a circular plate shape, a plurality of communication holes 52 arranged radially in a plurality of rows around the center of the plate body 51 and formed to penetrate through the plate body 51, and a first projection portion 53 that is formed to protrude from the center portion of a lower surface of the plate body 51 to a bottom surface 21 of the free space forming portion 20 and helps heat transfer from a disk 10 to the substrate S.

In addition, as shown in FIGS. 9 and 10, the cover plate 50 may include a second projection portion 54 that protrudes from the lower surface of the plate body 51 and has a second through hole formed therein to accommodate a substrate lift pin L. The free space forming portion 20 may include a concave groove 22 which is formed to be concave from the bottom surface 21 thereof at a position corresponding to the second projection portion 54 and accommodates the second projection portion 54.

Accordingly, at least a part of the second projection portion 54 of the cover plate 50 seated in the pocket groove 30 is inserted into the concave groove 22 so that the cover plate 50 is prevented from rotating inside the pocket groove 30, and the second projection portion 54 may support the plate body 51 at a predetermined height together with the first projection portion 53 so that the free space V can be formed below the cover plate 50.

At this time, the plate body 51 may be disposed in the free space forming portion 20 positioned inner than the stepped portion 31 at the same height as that of the stepped portion 31 such that an edge portion A3 of the substrate S can be supported by the stepped portion 31 and a center portion A1 and a middle portion A2 of the substrate S can be seated on the plate body 51.

For example, the plate body 51 may be formed in a plate shape having a size corresponding to an inner circumferential surface of the stepped portion 31, and the first projection portion 53 may be formed to protrude from a lower surface of the plate body 51 to a first height H1 so that an upper surface of the plate body 51 can be formed at the same height as that of the stepped portion 31.

However, the shape of the cover plate 50 is not necessarily limited thereto, and as shown in the substrate support 400 of FIG. 11 according to another embodiment of the present invention, the plate body 51 may be disposed on the stepped portion 31, allowing the entire substrate S to be seated thereon.

For example, the plate body 51 is formed in a circular plate shape having a size corresponding to an inner circumferential surface of the pocket groove 30, and the first projection portion 53 may be formed to protrude from the lower surface of the plate body 51 to a second height H2 to allow the lower surface of the plate body 51 to be seated on the stepped portion 31.

Accordingly, in the substrate supports 300 and 400 according to other embodiments of the present invention, the cover plate 50 transfers a suction force, which is generated by the vacuum pressure formed in the free space V, to the substrate S through the communication holes 52 while supporting the entire area of the lower surface of the substrate S, except for the area supported by the stepped portion 51, or the entire area of the lower surface of the substrate S, so that the substrate S is prevented from being dislodged from the pocket groove 30 due to various changes in process conditions, such as an instantaneous gas flow change or a sudden pressure change in the process chamber 910 during the process of processing the substrate S.

In addition, as shown in FIGS. 12 and 13, the cover plate 50 of the substrate support 500 according to yet another embodiment of the present invention, may include an extended portion 55 that is formed to extend from one side of the plate body 51 in a shape corresponding to the shape of the exhaust passage 40 and covers an upper portion of the exhaust passage 40.

Accordingly, the upper portion of the exhaust passage 40 is closed so that the processing gas injected from a shower head 920 can be effectively prevented from entering into the free space V formed below the substrate S seated on the pocket groove 30 through the exhaust passage 40 during the process of processing the substrate S. In addition, through the extended portion 55 of the cover plate 50, the heat of a disk 10 heated to the process temperature may be induced to be efficiently transferred from the exhaust passage 40 to the substrate S.

Therefore, as shown in (B) and (C) of FIG. 14, the substrate supports 300, 400, and 500 according to other embodiments of the present invention and the substrate processing apparatus 1000 including the substrate support 300, 400, or 500 may induce the pressure generated in the lower portion of the substrate S to be smaller than the pressure generated in the upper portion of the substrate S, thereby effectively preventing the substrates S from being dislodged from the pocket grooves 30 of the substrate supports 300, 400, and 500 during the process of processing the plurality of substrates S. Accordingly, it is possible to prevent the process defect of the substrate S from occurring due to a problem in which the substrate S is dislodged from the pocket groove 30 during the process of processing the substrate S and also to increase the yield.

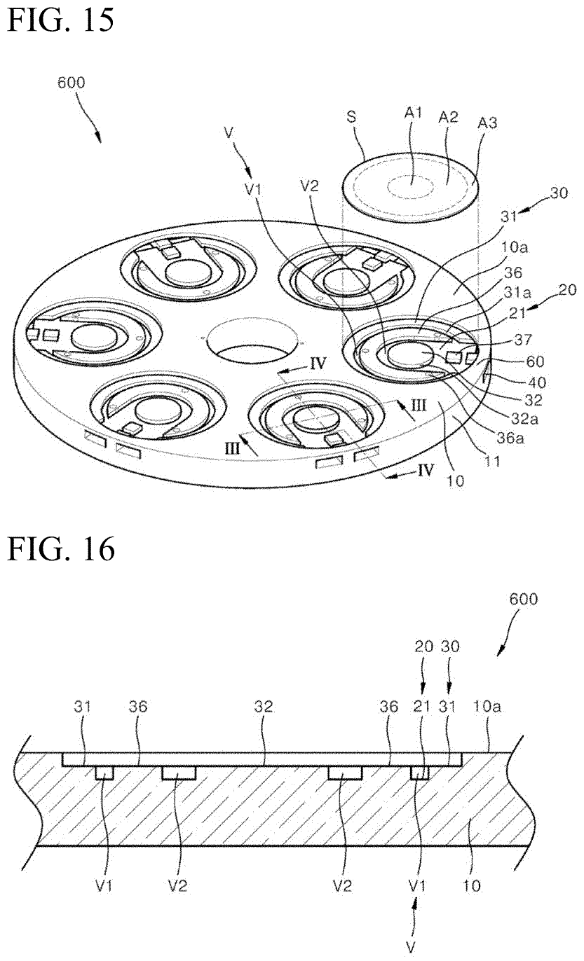

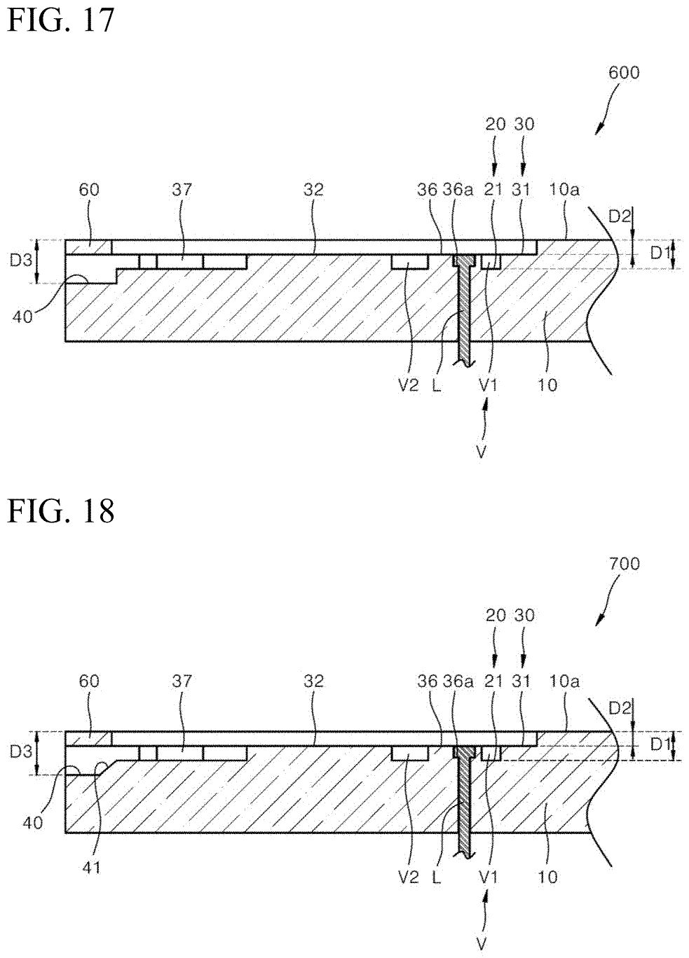

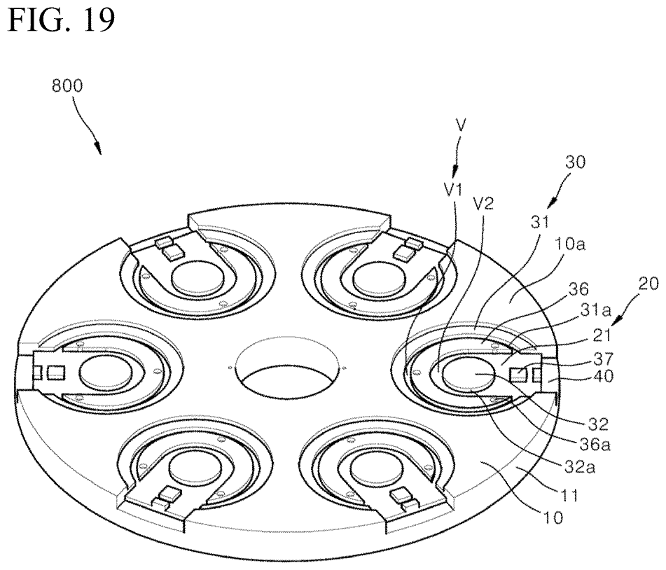

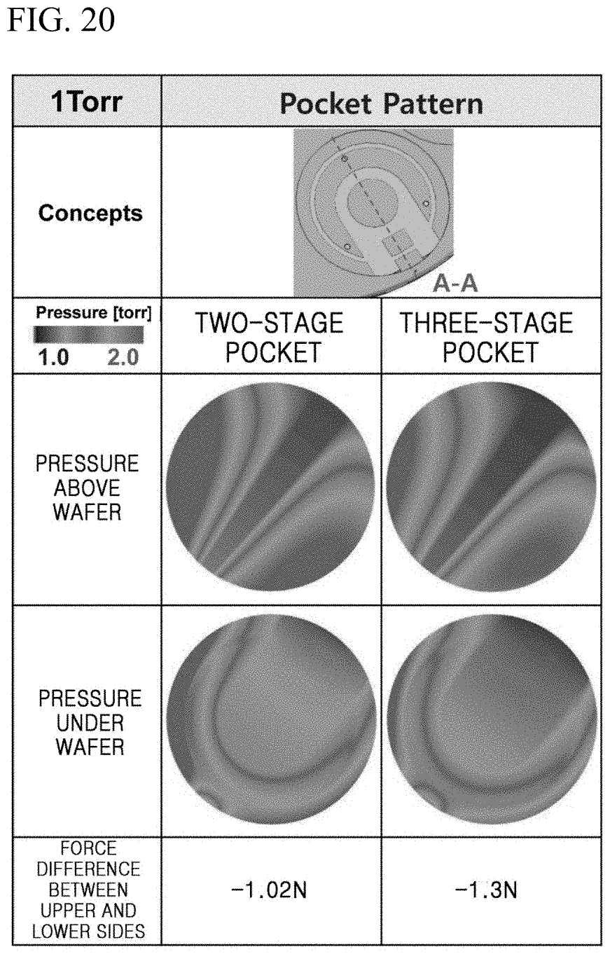

FIG. 15 is a perspective view schematically showing a substrate support 600 according to another embodiment of the present invention. In addition, FIG. 16 is a cross-sectional view schematically showing a cross section taken along line III-III of FIG. 15, FIG. 17 is a cross-sectional view schematically showing a cross section taken along line IV-IV of FIG. 15, and FIG. 18 is a cross-sectional view schematically showing another embodiment of the cross section taken along the line IV-IV of FIG. 15. Also, FIG. 19 is a perspective view schematically showing a substrate support 800 according to another embodiment of the present invention, and FIG. 20 is an image showing results of analyzing the pressure generated on upper and lower surfaces of a substrate seated in a pocket groove of a substrate support according to another embodiment of the present invention.

As shown in FIGS. 15 to 17, at least one pocket groove 30 of the substrate support 600 according to another embodiment of the present invention may be formed to be concave from an upper surface 10a of a disk 10 and in a shape corresponding to the substrate S such that at least an edge portion A3 of the substrate S can be seated. More specifically, a plurality of pocket grooves 30 may be formed to be concave to a second depth D2 from the upper surface 10a of the disk 10 and be arranged along a circumferential direction of the disk 10 around the rotation axis of the disk 10 such that a plurality of substrates S can be seated on the substrate support 600.

In addition, a free space forming portion 20 of the substrate support 600 may be spaced inwardly at a predetermined distance from an edge of the pocket groove 30 so as to define a stepped portion 31 that supports at least the edge portion A3 of the substrate S, and may be formed to be concave from at least a part of a bottom surface of the pocket groove 30 to have a first depth D1 that is deeper than the second depth D2. Accordingly, when the substrate S is seated on the stepped portion 31, a free space V may be formed below the substrate S.

For example, in the process of processing the substrate S, when a vacuum environment is formed by sucking in air from the inside of the process chamber 910 through an exhaust port E installed at the lower portion of the process chamber 910, vacuum pressure may be formed in the free space V of the pocket groove 30 formed by the free space forming portion 20, thereby generating a suction force that fixes the substrate S to the pocket groove 30.

In this case, an exhaust passage 40 including an inlet portion that is formed on at least a portion in contact with an outer circumferential surface of the disk 11 and is deeper than a bottom surface 21 of the free space forming portion 20 may be formed to connect the outer circumferential surface 11 of the disk 10 to at least a part of the free space forming portion 20, so that the air inside the free space V can be smoothly exhausted through the exhaust passage 40 and thereby a vacuum pressure can be formed. For example, the inlet portion of the exhaust passage 40 may be formed to have a bottom surface at a third depth D3 that is deeper than the first depth D1 of the bottom surface of the free space forming portion 20 from the upper surface 10a of the disk 10.

Thus, when the substrate S is seated in the pocket groove 30 of the substrate support 600, the free space V may be formed below the substrate S, which is seated in the pocket groove 30, by the free space forming portion 20. At this time, when the air inside the process chamber 910 is sucked through the exhaust port E formed on the lower portion of the process chamber 910, the air inside the free space V may be discharged to the exhaust port E through the exhaust passage 40, thereby generating the vacuum pressure in the free space V. Accordingly, the vacuum pressure generates a force to pull the lower surface of the substrate S seated on the pocket groove 30, so that the substrate S is prevented from being dislodged from the pocket groove 30 during the process of processing the substrate S.

In the free space forming portion 20, a heat transfer structure may be formed in a wide variety of forms in order to effectively transfer heat of the disk 10 heated to the process temperature by the heater to the substrate S while forming the free space V below the substrate (S) seated in the pocket groove 30.

For example, as shown in FIGS. 15 to 17, the free space forming portion 20 may include a first heat transfer portion 32 and a fourth heat transfer portion 36 wherein the first heat transfer portion is formed in a pillar shape protruding from the center of the bottom surface 21 of the free space forming portion 20 to the same height as that of the stepped portion 31 to help heat transfer from the disk 10 to the substrate S when the substrate S is seated on the stepped portion 31 and the fourth heat transfer portion 36 is formed between an inner circumferential surface 31a of the stepped portion 31 and an outer circumferential surface 32a of the first heat transfer portion 32 at the same height as that of the stepped portion 31 and protrudes in the shape of a ring which is open toward a direction of the exhaust passage 40.

In addition, the fourth heat transfer portion 36 may have a plurality of lift pin receiving grooves 36a formed to be concave from a surface of the fourth heat transfer portion 36 in a shape corresponding to a substrate lift pin L to accommodate therein a plurality of substrate lift pins L. For example, the lift pint receiving grooves 36a may be radially disposed around the center of a plurality of pocket grooves 30 and an upper surface of the substrate lift pins L received in the lift pin receiving grooves 36a may be formed at a height equal to or lower than the surface of the fourth heat transfer portion 36.

As such, the first heat transfer portion 32 and the fourth heat transfer portion 36 may serve to uniformly transfer heat generated from the disk 10, while supporting the lower surface of the substrate S in such a manner that the free space S can be formed below the substrate S in the pocket groove 30.

In addition, the free space V may be divided into a first free space V1 between the stepped portion 31 and the fourth heat transfer portion 36 and a second free space V2 between the fourth heat transfer portion 36 and the first heat transfer portion 32, and the stepped portion 31 and the fourth heat transfer portion 36 may be formed to be open in a direction of the exhaust passage 40 so that the first free space V1 and the second free space V2 can communicate with the exhaust passage 40.

At this time, the heat of the disk 10 may not be effectively transferred to the substrate S in the open areas of the stepped portion 31 and the fourth heat transfer portion 36 which are opened to allow the free space V to communicate with the exhaust passage 40, and thereby a problem may arise in that temperature distribution is not uniform across the substrate S.

For this reason, the free space forming portion may include a fifth heat transfer portion 37 that is formed in a pillar shape protruding from the bottom surface 21 of the free space forming portion 20 to the same height as that of the stepped portion 31 and is spaced apart from the first heat transfer portion 32 in a direction of the exhaust passage 40 so as to help heat transfer from the disk 10 to the substrate S when the substrate S is seated on the stepped portion 31. More specifically, a plurality of fifth heat transfer portions 37 may be disposed to be spaced apart from the first heat transfer portion 32 in a direction of the exhaust passage 40 and some of the fifth heat transfer portions 37 may be extended to the outer circumferential surface 11 of the disk 10 to divide the exhaust passage 40 into two sections so that the inlet of the exhaust passage 40 may be divided into two parts by the fifth heat transfer portions 37.

Thus, in the substrate support 600 according to one embodiment of the present invention, the first free space V1 and the second free space V2 are provided inside of the pocket groove 30 to form a ring shape as a whole by the free space forming portion 20, and a vacuum pressure is generated when a vacuum environment is formed inside the process chamber 910, so that the substrate S can be prevented from being dislodged from the pocket groove 30 due to various changes in process conditions, such as an instantaneous gas flow change or a sudden pressure change, in the process chamber 910 in the process of processing the substrate S.

In this case, in the free space V, the first heat transfer portion 32, the fourth heat transfer portion 36, and the fifth heat transfer portion 37 may be formed to uniformly transfer heat of the disk 10 heated to the process temperature to the entire area of the substrate S, while supporting the substrate S in such a manner that the free space V is formed inside of the pocket groove 30.

In addition, as shown in FIG. 17, in order to increase the cross-sectional area of the exhaust passage 40, the exhaust passage 40 may be formed such that an inlet portion thereof has a bottom surface at a third depth D3 that is deeper than the first depth D1 of the bottom surface of the free space forming portion 20 from the upper surface 10a of the disk 10.

Accordingly, the exhaust passage 40 is formed deeper than the bottom surface 21 of the free space V, which is formed in the pocket groove 30 by the free space forming portion, thereby increasing the cross-sectional area of the exhaust passage 40 through which the air inside of the free space V is discharged, and hence the air inside the free space V formed in the pocket groove 30 is allowed to be discharged more quickly and strongly and the vacuum pressure generated in the free space V may thus be increased even more.

Accordingly, as shown in the simulation results of FIG. 20, a pressure difference of upper and lower surfaces of the substrate S in a two-stage pocket in which the bottom surface 21 of the free space V and the exhaust passage 40 are formed at the same depth is −1.02N, and a pressure difference of upper and lower surfaces of the substrate S in a three-stage pocket in which the exhaust passage 40 is formed at the third depth D3 that is deeper than the first depth D1 of the bottom surface 21 of the free space V is −1.3N, which is much greater than that of the former case. As can be seen in the above results, a suction force for the substrate S in the pocket groove 30 may be more increased by the exhaust passage 40 that is formed deeper than the free space V formed inside the pocket groove 30.

In addition, as shown in FIG. 18, an exhaust passage 40 of a substrate support 700 according to another embodiment of the present invention may include an inclined portion 41 with a depth linearly increasing from a free space forming portion 20 to an inlet portion, between the free space forming portion 20 and the inlet portion. Accordingly, a stepped shape is prevented from being formed at the boundary between the free space V having a varying depth and the exhaust passage 40, so that the flow of air exhausted through the exhaust passage 40 in the free space V inside the pocket groove 30 can be more smoothly induced.

Further, the substrate supports 600 and 700 according to various embodiments of the present invention may include a cover portion 60 to cover at least the inlet portion of the exhaust passage 40 such that the inlet portion of the exhaust passage 40 is in the shape of a tunnel. Accordingly, the upper portion of the exhaust passage 40 is covered, thereby various processing gases injected from the shower head 920 from entering into the free space V inside the pocket groove 30 through the exhaust passage 40 during the process of processing the substrate S.

However, the present invention is not necessarily limited thereto, and as shown in the substrate support 800 of FIG. 19 according to another embodiment of the present invention, the exhaust passage 40 may be formed in a shape with an open upper portion. The cover portion 60 may be optionally applied according to various processing conditions, such as injection pressures of various processing gases injected from the shower head 920.

Therefore, the substrate supports 600, 700, and 800 according to various embodiments of the present invention and the substrate processing apparatus 1000 including the substrate support 600, 700, or 800 may induce the pressure generated in the lower portion of the substrate S to be smaller than the pressure generated in the upper portion of the substrate S, thereby effectively preventing the substrates S from being dislodged from the pocket grooves 30 of the substrate supports 600, 700, and 800 during the process of processing the plurality of substrates S. Accordingly, it is possible to prevent the process defect of the substrate S from occurring due to a problem in which the substrate S is dislodged from the pocket groove 30 during the process of processing the substrate S and also to increase the yield.

According to the substrate processing apparatus in accordance with one embodiment of the present invention made as described above, it is possible to prevent substrates from being dislodged from pocket grooves of the substrate support during the process of processing a plurality of substrates. Therefore, it is possible to implement the substrate processing apparatus having an effect of preventing a process defect of the substrate from occurring due to a problem in which the substrate is dislodged from the pocket groove during the process of processing the substrate. It is apparent that the scope of the present invention is not limited by such effects.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

### REFERENCE NUMERALS

10: DISK
20: FREE SPACE FORMING PORTION
30: POCKET GROOVE
40: EXHAUST PASSAGE
50: COVER PLATE
60: COVER PORTION
S: SUBSTRATE
V: FREE SPACE
E: EXHAUST PORT
100, 200, 300, 400, 500, 600, 700, 800: SUBSTRATE SUPPORT
910: PROCESS CHAMBER
920: SHOWER HEAD
930: VACUUM PUMP
1000: SUBSTRATE PROCESSING APPARATUS

What is claimed is:

1. A substrate processing apparatus comprising:
a process chamber in which a processing space for processing a substrate is formed;
a substrate support provided in the processing space of the process chamber to support the substrate; and
a shower head which is provided in an upper portion of the process chamber to face the substrate support and injects a processing gas toward the substrate support,
wherein the substrate support comprises
a disk formed in a disk shape to support at least one substrate,
at least one pocket groove which is formed to be concave from an upper surface of the disk in a shape corresponding to the substrate such that at least an edge portion of the substrate is seated therein,
a free space forming portion which is spaced inwardly at a predetermined distance from an edge of the pocket groove and formed to be concave from at least a part of a bottom surface of the pocket groove so as to define a stepped portion that supports at least the edge portion of the substrate and forms a free space below the substrate when the substrate is seated on the stepped portion, and
an exhaust passage which connects an outer circumferential surface of the disk to at least a part of the free space forming portion.

2. The substrate processing apparatus of claim 1, wherein the free space forming portion includes a first heat transfer portion formed to protrude from a center portion of a bottom surface of the free space forming portion to the same height as that of the stepped portion so as to help heat transfer from the disk to the substrate when the substrate is seated on the stepped portion.

3. The substrate processing apparatus of claim 2, wherein the free space forming portion includes a second heat transfer portion that extends from one side of the first heat transfer portion in a direction of the exhaust passage and is formed to protrude from the bottom surface of the free space forming portion to the same height as that of the stepped portion to help heat transfer from the disk to the substrate when the substrate S is seated on the stepped portion.

4. The substrate processing apparatus of claim 1, wherein the free space forming portion includes a third heat transfer portion formed in the exhaust passage to protrude from a bottom surface of the free space forming portion to the same height as that of the stepped portion so as to help heat transfer from the disk to the substrate when the substrate is seated on the stepped portion.

5. The substrate processing apparatus of claim 1, wherein the free space forming portion includes a plurality of lift pin receiving grooves which are formed to protrude from a bottom surface of the free space forming portion to the same height as that of the stepped portion and each include a through-hole formed to accommodate therein a substrate lift pin.

6. The substrate processing apparatus of claim 1, further comprising a cover plate disposed in the pocket groove to allow at least a part of the substrate to be seated and including a plurality of communication holes communicating with the free space forming portion.

7. The substrate processing apparatus of claim 6, wherein
the cover plate includes
a plate body formed in a circular plate shape; and
a first projection portion that is formed to protrude from a center portion of a lower surface of the plate body to a bottom surface of the free space forming portion and helps heat transfer from the disk to the substrate.

8. The substrate processing apparatus of claim 7, wherein
the cover plate includes a second projection portion that is formed to protrude from the lower surface of the plate body and has a through-hole to accommodate therein a substrate lift pin and
the free space forming portion includes a concave groove which is formed to be concave from the bottom surface thereof at a position corresponding to the second projection portion and accommodates the second projection portion.

9. The substrate processing apparatus of claim 7, wherein the plate body is disposed on the stepped portion to allow the entire substrate to be seated on an upper portion of the plate body.

10. The substrate processing apparatus of claim 7, wherein the plate body is disposed in the free space forming portion positioned inner than the stepped portion at the same height as that of the stepped portion such that the edge portion of the substrate is supported by the stepped portion and a center portion of the substrate is seated on the plate body.

11. The substrate processing apparatus of claim 7, wherein the cover plate includes an extended portion that is formed to extend from one side of the plate body in a shape corresponding to a shape of the exhaust passage and covers an upper portion of the exhaust passage.

12. The substrate processing apparatus of claim 1, wherein the exhaust passage has an inlet portion that is formed on at least a portion in contact with an outer circumferential surface of the disk and is deeper than a bottom surface of the free space forming portion.

13. The substrate processing apparatus of claim 12, wherein the free space forming portion includes a first heat transfer portion formed to protrude from a center portion of a bottom surface of the free space forming portion to the same height as that of the stepped portion so as to help heat transfer from the disk to the substrate when the substrate is seated on the stepped portion.

14. The substrate processing apparatus of claim 13, wherein the free space forming portion includes a fourth heat transfer portion that is formed to protrude from the bottom surface of the free space forming portion to the same height as that of the stepped portion to help heat transfer from the disk to the substrate when the substrate is seated on the stepped portion and is spaced apart from the first heat transfer portion in a direction of the exhaust passage.

15. The substrate processing apparatus of claim 14, wherein a plurality of fourth heat transfer portions are disposed to be spaced apart from the first heat transfer portion in the direction of the exhaust passage.

16. The substrate processing apparatus of claim 15, wherein some of the fourth heat transfer portions are extended to the outer circumferential surface of the disk to divide the exhaust passage into two sections and the inlet portion of the exhaust passage is divided into two parts by the fourth heat transfer portion.

17. The substrate processing apparatus of claim 13, wherein the free space forming portion includes a fifth heat transfer portion that is formed between the stepped portion and the first heat transfer portion at the same height as that of the stepped portion and protrudes in a shape of a ring which is open toward a direction of the exhaust passage.

18. The substrate processing apparatus of claim 17, wherein the fifth heat transfer portion includes a plurality of lift pin receiving grooves formed to be concave from a surface of the fifth heat transfer portion in a shape corresponding to a substrate lift pin so as to accommodate therein a plurality of substrate lift pins.

19. The substrate processing apparatus of claim 12, further comprising a cover portion which covers at least the inlet portion of the exhaust passage such that the inlet portion is in the form of a tunnel.

20. The substrate processing apparatus of claim 12, wherein the exhaust passage includes an inclined portion with a depth linearly increasing from the free space forming portion to the inlet portion, between the free space forming portion and the inlet portion.
